(19) United States
(12) Patent Application Publication
(10) Pub. No.: US 2025/0140451 A1
(43) Pub. Date: May 1, 2025

(54) VARISTOR COMPONENT AND DIFFERENTIAL COMMUNICATION DEVICE

(71) Applicant: Panasonic Intellectual Property Management Co., Ltd., Osaka (JP)

(72) Inventors: Takeshi FUJII, Osaka (JP); Yasuhiko SASAKI, Hokkaido (JP); Yoshiyuki SAITO, Tokyo (JP); Tomohide KAMIYAMA, Osaka (JP); Masaya HATTORI, Tokyo (JP); Ken YANAI

(21) Appl. No.: 18/719,645

(22) PCT Filed: Dec. 19, 2022
(86) PCT No.: PCT/JP2022/046678

§ 371 Date: Jun. 13, 2024

(30) Foreign Application Priority Data
Dec. 21, 2021 (JP) 2021-207311

(51) Int. Cl. H01C 7/10; H01C 1/14; H04B 1/40

(52) U.S. Cl. CPC H01C 7/10; H01C 1/14; H04B 1/40

(57) ABSTRACT

A varistor component includes a first varistor element and a second varistor element. The electrostatic capacitance of the first varistor element and the electrostatic capacitance of the second varistor element are different.

### CROSS-REFERENCE OF RELATED APPLICATIONS

This application is the U.S. National Phase under 35 U.S.C. § 371 of International Patent Application No. PCT/JP2022/046678, filed on Dec. 19, 2022, which in turn claims the benefit of Japanese Patent Application No. 2021-207311, filed on Dec. 21, 2021, the entire disclosure of which applications are incorporated by reference herein.

### TECHNICAL FIELD

The present disclosure relates to a varistor component and a differential communication device including the varistor component.

### BACKGROUND ART

Communication devices that utilize the in-vehicle communication standard Controller Area Network (CAN) are known. In CAN, a differential transmission method is adopted in which data is transmitted by a voltage difference between two communication lines. To safely transmit data, noise countermeasures and overvoltage protection measures are necessary.

Patent Literature (PTL) 1 discloses a communication device that includes a common mode filter and an Electro-Static Discharge (ESD) protection element in order to implement noise countermeasures and overvoltage protection measures. PTL 1 also discloses using a varistor element as the ESD protection element.

PTL 2 discloses a stacked varistor component that includes two varistor elements. This varistor component includes a varistor-material sintered body, a plurality of external terminals, and a plurality of internal electrodes.

### CITATION LIST

### Patent Literature

[PTL 1] Japanese Unexamined Patent Application Publication No. 2019-205119
[PTL 2] Japanese Unexamined Patent Application Publication No. 2020-96075

### SUMMARY OF INVENTION

### Technical Problem

For example, when the varistor component described in PTL 2 is used as the ESD protection element of the differential communication device described in PTL 1, communication quality such as the immunity tolerance of the differential communication device may degrade.

The present disclosure provides a varistor component that can inhibit the degradation of communication quality of a differential communication device. The present disclosure provides a differential communication device that can inhibit the degradation of communication quality.

### Solution to Problem

A varistor component according to one aspect of the present disclosure includes a first varistor element and a second varistor element. An electrostatic capacitance of the first varistor element and an electrostatic capacitance of the second varistor element are different.

A varistor component according to one aspect of the present disclosure includes: a first varistor element; a second varistor element; a varistor-material sintered body; a first internal electrode, a second internal electrode, and a third internal electrode provided inside the varistor-material sintered body; and a first external terminal connected to the first internal electrode, a second external terminal connected to the second internal electrode, and a third external terminal connected to the third internal electrode. The first internal electrode includes a first main electrode and a first auxiliary electrode that are not connected to each other. The second internal electrode includes a second main electrode and a second auxiliary electrode that are not connected to each other. The first external terminal includes a first main terminal and a first auxiliary terminal that are not connected to each other. The second external terminal includes a second main terminal and a second auxiliary terminal that are not connected to each other. The first main electrode is connected to the first main terminal. The first auxiliary electrode is connected to the first auxiliary terminal. The second main electrode is connected to the second main terminal. The second auxiliary electrode is connected to the second auxiliary terminal. At least a portion of the first main electrode and at least a portion of the first auxiliary electrode oppose the third internal electrode. At least a portion of the second main electrode and at least a portion of the second auxiliary electrode oppose the third internal electrode. An electrostatic capacitance formed by the first main electrode and the third internal electrode is same as an electrostatic capacitance formed by the second main electrode and the third internal electrode. An electrostatic capacitance formed by the first auxiliary electrode and the third internal electrode is same as an electrostatic capacitance formed by the second auxiliary electrode and the third internal electrode.

A differential communication device according to one aspect of the present disclosure include: a transceiver IC; a common mode filter connected to the transceiver IC; and the above-described varistor component connected to the common mode filter.

A differential communication device according to one aspect of the present disclosure includes: a substrate on which a differential line including a first line and a second line is provided; a transceiver IC mounted on the substrate; a common mode filter mounted on the substrate and connected to the transceiver IC; and the above-described varistor component mounted on the substrate and connected to the common mode filter.

A differential communication device according to one aspect of the present disclosure includes: a substrate on which a differential line including a first line and a second line is provided; a transceiver IC mounted on the substrate; a common mode filter mounted on the substrate and connected to the transceiver IC; and the above-described varistor component mounted on the substrate and connected to the common mode filter. The first external terminal of the varistor component is connected to the first line, and each of the second main terminal and the second auxiliary terminal of the second external terminal of the varistor component is connected to the second line.

A differential communication device according to one aspect of the present disclosure includes: a substrate on which a differential line including a first line and a second line is provided; a transceiver IC mounted on the substrate; a common mode filter mounted on the substrate and connected to the transceiver IC; and the above-described varistor component mounted on the substrate and connected to the common mode filter. The first main terminal of the first external terminal of the varistor component is connected to the first line, the first auxiliary terminal of the first external terminal of the varistor component is not connected to the first line, and each of the second main terminal and the second auxiliary terminal of the second external terminal of the varistor component is connected to the second line.

A differential communication device according to one aspect of the present disclosure includes: a substrate on which a differential line including a first line and a second line is provided; a transceiver IC mounted on the substrate; a common mode filter mounted on the substrate and connected to the transceiver IC; and the above-described varistor component mounted on the substrate and connected to the common mode filter. The second main terminal of the second external terminal of the varistor component is connected to the second line, the second auxiliary terminal of the second external terminal of the varistor component is not connected to the second line, and each of the first main terminal and the first auxiliary terminal of the first external terminal of the varistor component is connected to the first line.

### Advantageous Effects of Invention

The varistor component according to the present disclosure can inhibit the degradation of communication quality of a differential communication device. The differential communication device according to the present disclosure can inhibit the degradation of communication quality.

### BRIEF DESCRIPTION OF DRAWINGS

FIG. 1 is a circuit diagram illustrating a differential communication device according to an embodiment of the present disclosure.

FIG. 2 is perspective view illustrating a varistor component according to an embodiment of the present disclosure.

FIG. 3 is a see-through view illustrating internal electrodes and the like of a varistor component according to an embodiment of the present disclosure in a view facing the top surface.

FIG. 4 is a cross-sectional view of a varistor component according to an embodiment of the present disclosure.

FIG. 5 illustrates a varistor component and a substrate on which the varistor component is mounted according to an embodiment of the present disclosure.

FIG. 6 illustrates a differential communication device for measurement and evaluation.

FIG. 7 is perspective view illustrating a varistor component according to a comparative example.

FIG. 8 is a see-through view illustrating internal electrodes and the like of a varistor component according to a comparative example in a view facing the top surface.

FIG. 9 is a cross-sectional view of a varistor component according to a comparative example.

FIG. 10 illustrates the relationship between the electrostatic capacitance of a varistor component according to a comparative example and Sdc11 of the differential communication device.

FIG. 11 illustrates the relationship between the electrostatic capacitance of a varistor component according to a comparative example and Sdc11 of the differential communication device at a predetermined frequency.

FIG. 12 illustrates the relationship between the electrostatic capacitance of a varistor component according to an implementation example, which is one example of an embodiment according to the present disclosure, and Sdc11 of the differential communication device.

FIG. 13 illustrates the relationship between the electrostatic capacitance of a varistor component according to an implementation example, which is one example of an embodiment according to the present disclosure, and Sdc11 of the differential communication device at a predetermined frequency.

FIG. 14 compares Sdc11 of a differential communication device in a comparative example and the implementation example.

FIG. 15 illustrates a varistor component according to Variation 1 of an embodiment of the present disclosure.

FIG. 16 is a perspective view illustrating a varistor component according to Variation 2 of an embodiment of the present disclosure.

FIG. 17 is a see-through view illustrating internal electrodes and the like of a varistor component according to Variation 2 of an embodiment of the present disclosure in a view facing the top surface.

FIG. 18 is a cross-sectional view illustrating a varistor component according to Variation 2 of an embodiment of the present disclosure.

FIG. 19 illustrates a varistor component and a substrate on which the varistor component is mounted according to Variation 2 of an embodiment of the present disclosure.

FIG. 20 is a perspective view illustrating a varistor component according to Variation 3 of an embodiment of the present disclosure.

FIG. 21 is a see-through view illustrating internal electrodes and the like of a varistor component according to Variation 3 of an embodiment of the present disclosure in a view facing the top surface.

FIG. 22 is a cross-sectional view illustrating a varistor component according to Variation 3 of an embodiment of the present disclosure.

FIG. 23 illustrates a varistor component and a substrate on which the varistor component is mounted according to Variation 3 of an embodiment of the present disclosure.

### DESCRIPTION OF EMBODIMENTS

### Embodiment

### Configuration of Differential Communication Device

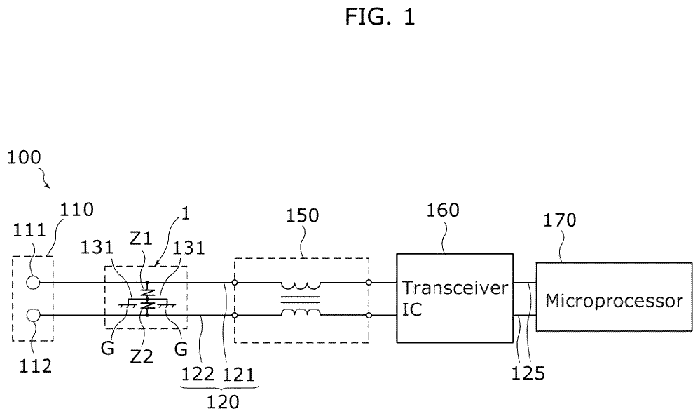

First, a differential communication device according to an embodiment of the present disclosure will be described with reference to FIG. 1.

FIG. 1 is a circuit diagram illustrating differential communication device 100 according to an embodiment of the present disclosure.

Differential communication device 100 is a device that utilizes communication using a differential transmission method. As illustrated in FIG. 1, differential communication device 100 includes connector 110, varistor component 1, common mode filter 150, transceiver IC 160, and microprocessor 170.

Differential communication device 100 also includes differential lines 120, namely first line 121 and second line 122, and control signal line 125. First line 121 is a line connecting first input/output terminal 111 of connector 110 and transceiver IC 160. Second line 122 is a line connecting second input/output terminal 112 of connector 110 and transceiver IC 160. Control signal line 125 is a line connecting transceiver IC 160 and microprocessor 170. For example, varistor component 1, common mode filter 150, transceiver IC 160, first line 121, and second line 122 are provided on the same single substrate (not illustrated).

Differential communication device 100 is provided in a vehicle and communicates with other differential communication devices in the vehicle via an in-vehicle network. A harness is connected to differential communication device 100. The harness is a bus line for performing communication with other differential communication devices. For example, a Controller Area Network (CAN) is used as the in-vehicle network.

Transceiver IC 160 executes various application processes which differ depending on the in-vehicle equipment. For example, when the in-vehicle equipment is infotainment equipment (for example, a car navigation device or display/audio device), microprocessor 170 executes image signal processing and/or audio signal processing. Transceiver IC 160 converts the differential transmission signal received via the harness into a digital signal to be processed by microprocessor 170. Transceiver IC 160 also converts the digital signal processed by microprocessor 170 into a differential transmission signal and transmits the converted differential transmission signal to other differential communication devices via the harness.

Connector 110 includes first input/output terminal 111 and second input/output terminal 112. The harness is connected to first input/output terminal 111 and second input/output terminal 112, and the differential transmission signal is input and output via first input/output terminal 111 and second input/output terminal 112.

Varistor component 1 includes first varistor element Z1 and second varistor element Z2.

First varistor element Z1 is provided on the path connecting first line 121 and ground G. More specifically, one terminal of first varistor element Z1 is connected to a node on first line 121 between first input/output terminal 111 and common mode filter 150, and the other terminal of first varistor element Z1 is connected to ground line 131 that leads to ground G.

Second varistor element Z2 is provided on the path connecting second line 122 and ground G. More specifically, one terminal of second varistor element Z2 is connected to a node on second line 122 between second input/output terminal 112 and common mode filter 150, and the other terminal of second varistor element Z2 is connected to ground line 131 that leads to ground G. Note that ground G is a reference potential of differential communication device 100 and is realized by being electrically connected to, for example, a vehicle body earth.

First varistor element Z1 and second varistor element Z2 are capable of drawing current from each node to ground G by conducting under predetermined voltage conditions. Therefore, even when a large current flows through first line 121 and second line 122, the current flowing into transceiver IC 160 can be inhibited to protect transceiver IC 160.

Common mode filter 150 is inserted on first line 121 and second line 122, which are differential lines 120 connecting connector 110 and transceiver IC 160. Common mode filter 150 passes signal current and attenuates common mode noise current. Much of the noise superimposed on differential line 120 is common mode noise, which common mode filter 150 attenuates.

For example, when common mode filter 150 is formed by a wound coil having a large common mode inductance, the parasitic capacitance and length of the two windings forming a differential signal pair may differ, and the impedances of the two wound coils forming the differential signal pair may differ. When the impedances of the two wound coils differ, an imbalance occurs in differential line 120, and the common mode component of the differential transmission signal may be converted into a differential mode component. Therefore, in conventional techniques, communication quality such as the immunity tolerance of the differential communication device may degrade.

In differential communication device 100 according to the present disclosure, by using varistor component 1 in which the electrostatic capacitance of first varistor element Z1 and the electrostatic capacitance of second varistor element Z2 differ, the imbalance of differential line 120 is corrected. With this, the degradation of communication quality such as the immunity tolerance of differential communication device 100 can be inhibited.

Hereinafter, one or more embodiments of the present disclosure will be described in detail with reference to the drawings.

Each embodiment illustrates one specific example of the present disclosure. The numerical values, shapes, materials, elements, the arrangement and connection of the elements, steps, order of the steps, etc., shown in the following embodiments are mere examples, and therefore do not limit the scope of the present disclosure. Accordingly, among the elements in the following embodiments, those not recited in any of the independent claims are described as optional elements.

In the present specification, numerical ranges are expressions that include, in addition to their exact meanings, substantially equivalent ranges, including differences of approximately a few percent, for example.

The figures are schematic illustrations, appropriately emphasized, omitted, or adjusted in ratio to represent the present disclosure, are not necessarily precise depictions, and may differ from actual shapes, positional relationships, and ratios. In the figures, the same reference signs are used for elements that are essentially the same. Accordingly, duplicate description may be omitted or simplified.

### Varistor Component Configuration

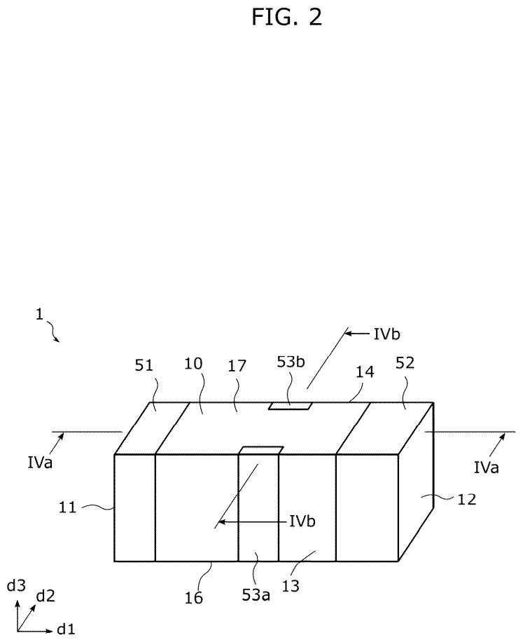

The configuration of the varistor component according to an embodiment of the present disclosure will be described with reference to FIG. 2 through FIG. 5. The varistor component is a stacked component in which a plurality of external terminals are formed on a varistor-material sintered body that includes a plurality of ceramic layers and a plurality of internal electrode layers.

FIG. 2 is perspective view illustrating varistor component 1 according to an embodiment of the present disclosure. Note that in FIG. 2, illustration of the thickness of the external terminals is omitted.

Varistor component 1 illustrated in FIG. 2 includes varistor-material sintered body 10, a plurality of external terminals provided outside varistor-material sintered body 10, and a plurality of internal electrodes provided inside varistor-material sintered body 10.

Varistor-material sintered body 10 includes ZnO as a main component, and Bi₂O₃, Co₂O₃, MnO₂, Sb₂O₃, etc., or Pr₆O₁₁, Co₂O₃, CaCO₃, Cr₂O₃, etc., as subcomponents. Varistor-material sintered body 10 is formed by sintering ZnO, with the other subcomponents precipitating at the grain boundaries thereof.

Varistor-material sintered body 10 is rectangular parallelepiped-shaped, and includes bottom surface 16 and top surface 17 facing in opposite directions, and a plurality of side surfaces connecting bottom surface 16 and top surface 17. Bottom surface 16, top surface 17, and the plurality of side surfaces are each flat surfaces. The plurality of side surfaces include first side surface 11 perpendicular to bottom surface 16 and top surface 17, second side surface 12 facing in an opposite direction from that of first side surface 11, and third side surface 13 and fourth side surface 14 perpendicular to both first side surface 11 and bottom surface 16. Third side surface 13 and fourth side surface 14 face in opposite directions.

Bottom surface 16 and top surface 17 are parallel to each other, first side surface 11 and second side surface 12 are parallel to each other, and third side surface 13 and fourth side surface 14 are parallel to each other. The corner portions (ridge portions) where any two surfaces of varistor-material sintered body 10 intersect may have a rounded shape.

Here, a direction parallel to the opposite directions in which first side surface 11 and second side surface 12 face is defined as first direction d1, a direction parallel to the opposite directions in which third side surface 13 and fourth side surface 14 face is defined as second direction d2, and a direction parallel to the opposite directions in which bottom surface 16 and top surface 17 face is defined as third direction d3. For example, in varistor-material sintered body 10, the length dimension in first direction d1 is greater than the width dimension in second direction d2, and the height dimension in third direction d3 is smaller than the length dimension in first direction d1. The plurality of external terminals include first external terminal 51, second external terminal 52, and third external terminals 53a and 53b. First external terminal 51, second external terminal 52, and third external terminals 53a and 53b are not electrically connected to each other.

First external terminal 51 is provided on first side surface 11. First external terminal 51 is a terminal on one end of first varistor element Z1 and is connected to first line 121.

Second external terminal 52 is provided on second side surface 12. Second external terminal 52 is a terminal on one end of second varistor element Z2 and is connected to second line 122.

Third external terminals 53a and 53b are provided on a portion of third side surface 13 and a portion of fourth side surface 14, respectively. Third external terminals 53a and 53b are arranged on third side surface 13 and fourth side surface 14 such that, when viewed from second direction d2, they are located between first external terminal 51 and second external terminal 52. Third external terminals 53a and 53b are common terminals on the other end of first varistor element Z1 and the other end of second varistor element Z2, and are connected to ground G via ground line 131.

Note that third external terminals 53a and 53b are also provided on a portion of bottom surface 16 and a portion of top surface 17. First external terminal 51 is also provided on a portion of each of bottom surface 16, top surface 17, third side surface 13, and fourth side surface 14 so as to connect to the portion of first external terminal 51 on first side surface 11. Second external terminal 52 is also provided on a portion of each of bottom surface 16, top surface 17, third side surface 13, and fourth side surface 14, in regions other than regions where first external terminal 51 is provided, so as to connect to the portion of second external terminal 52 on second side surface 12. In order to distinguish between first external terminal 51 and second external terminal 52, on each of bottom surface 16, top surface 17, third side surface 13, and fourth side surface 14, the length of second external terminal 52 in first direction d1 is longer than the length of first external terminal 51 in first direction d1.

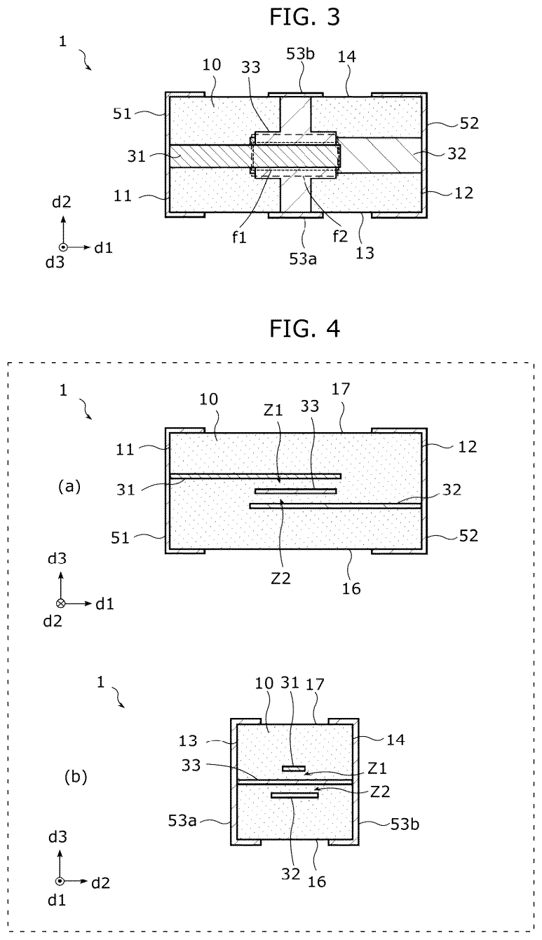

FIG. 3 is a see-through view illustrating the internal electrodes and the like of varistor component 1 in a view facing top surface 17. FIG. 4 is a cross-sectional view of varistor component 1. In FIG. 4, (a) is a view of varistor component 1 as seen from line IVa-IVa illustrated in FIG. 2, and (b) is a view of varistor component 1 as seen from line IVb-IVb illustrated in FIG. 2.

The plurality of internal electrodes of varistor component 1 illustrated in FIG. 3 and FIG. 4 include first internal electrode 31, second internal electrode 32, and third internal electrode 33.

First internal electrode 31 is connected to first external terminal 51 at first side surface 11, second internal electrode 32 is connected to second external terminal 52 at second side surface 12, and third internal electrode 33 is connected to third external terminals 53a and 53b at at least one of third side surface 13 or fourth side surface 14. Stated differently, first internal electrode 31 is connected to first line 121 via first external terminal 51, second internal electrode 32 is connected to second line 122 via second external terminal 52, and third internal electrode 33 is connected to ground G via third external terminals 53a and 53b.

First internal electrode 31, second internal electrode 32, and third internal electrode 33 are each formed on different ceramic layers. Each of first internal electrode 31, second internal electrode 32, and third internal electrode 33 is provided parallel to bottom surface 16 or top surface 17.

First internal electrode 31 is arranged closer to top surface 17 than third internal electrode 33 is. Stated differently, first internal electrode 31 and second internal electrode 32 are provided on opposite sides of third internal electrode 33, and at least a portion of first internal electrode 31 opposes third internal electrode 33. For example, first internal electrode 31 is rectangular when viewed from third direction d3, and extends from first side surface 11 toward second side surface 12 beyond opposing region f1 in which first internal electrode 31 opposes third internal electrode 33. Opposing region f1 is a region that exhibits a function as a varistor, and has a structure in which first internal electrode 31 and third internal electrode 33 oppose each other with a varistor sintered material interposed therebetween.

Second internal electrode 32 is arranged closer to bottom surface 16 than third internal electrode 33 is. Stated differently, first internal electrode 31 and second internal electrode 32 are provided on opposite sides of third internal electrode 33, and at least a portion of second internal electrode 32 opposes third internal electrode 33. For example, second internal electrode 32 is rectangular when viewed from third direction d3, and extends from second side surface 12 toward first side surface 11 beyond opposing region f2 in which second internal electrode 32 opposes third internal electrode 33. Opposing region f2 is a region that exhibits a function as a varistor, and has a structure in which second internal electrode 32 and third internal electrode 33 oppose each other with a varistor sintered material interposed therebetween.

Third internal electrode 33 is provided between first internal electrode 31 and second internal electrode 32. Third internal electrode 33 is provided along second direction d2 so as to connect a portion of third side surface 13 and a portion of fourth side surface 14. Third internal electrode 33 has a plus (+) shape such that, in the vicinity of opposing regions f1 and f2, the length in first direction d1 is longer than the length exposed on a portion of third side surface 13 and a portion of fourth side surface 14.

The value of electrostatic capacitance C1 of first varistor element Z1 is a value that varies depending on the opposing surface area of opposing region f1 in which first internal electrode 31 and third internal electrode 33 oppose each other. The value of electrostatic capacitance C2 of second varistor element Z2 is a value that varies depending on the opposing surface area of opposing region f2 in which second internal electrode 32 and third internal electrode 33 oppose each other.

In the present embodiment, the opposing surface area of first internal electrode 31 and third internal electrode 33 and the opposing surface area of second internal electrode 32 and third internal electrode 33 are different, and thus electrostatic capacitance C1 of first varistor element Z1 and electrostatic capacitance C2 of second varistor element Z2 are different. More specifically, the opposing surface area of second internal electrode 32 and third internal electrode 33 is larger than the opposing surface area of first internal electrode 31 and third internal electrode 33, and electrostatic capacitance C2 of second varistor element Z2 is greater than electrostatic capacitance C1 of first varistor element Z1 (C1<C2). For example, it is desirable that electrostatic capacitance C2 is greater than or equal to 1.01 times and less than or equal to 1.12 times electrostatic capacitance C1.

The width dimension of second internal electrode 32 in second direction d2 is greater than the width dimension of first internal electrode 31 in second direction d2. The width dimension (dimension in second direction d2) of third internal electrode 33 in opposing regions f1 and f2 is greater than each of the width dimensions of first internal electrode 31 and second internal electrode 32. The gap between first internal electrode 31 and third internal electrode 33 in opposing region f1 is the same as the gap between second internal electrode 32 and third internal electrode 33 in opposing region f2.

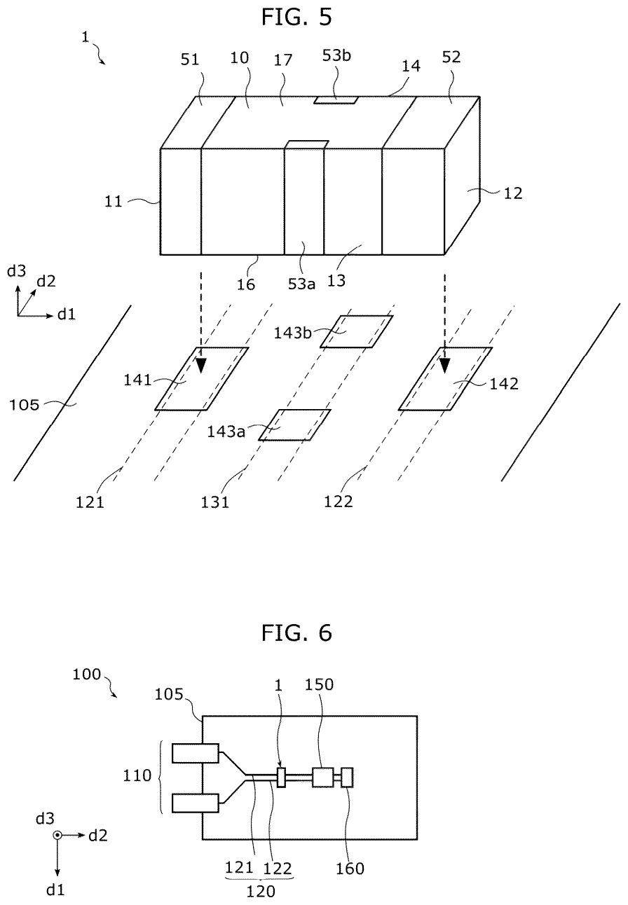

FIG. 5 illustrates varistor component 1 and substrate 105 on which varistor component 1 is mounted.

As illustrated in FIG. 5, first line 121, second line 122, and ground line 131 are formed on substrate 105. Substrate 105 is also provided with first land electrode 141 for connecting first line 121 and first external terminal 51, second land electrode 142 for connecting second line 122 and second external terminal 52, and third land electrodes 143a and 143b for connecting ground line 131 and third external terminals 53a and 53b. For example, each land electrode is formed by applying a resist on substrate 105 to regions other than regions that are to be the land electrodes. Each land electrode is exposed like an open window on substrate 105 before varistor component 1 is mounted.

When mounting varistor component 1 on substrate 105, first external terminal 51, second external terminal 52, and third external terminals 53a and 53b are respectively connected to first land electrode 141, second land electrode 142, and third land electrodes 143a and 143b via solder. Note that when ground line 131 is provided inside substrate 105, ground line 131 and third land electrodes 143a and 143b are connected via a via conductor (not illustrated) inside substrate 105.

For example, when the impedances of the two wound coils of common mode filter 150 differ, an imbalance occurs in differential line 120. Which of the two lines of differential line 120 is connected to the wound coil with higher impedance can be determined by the orientation of markings such as the model number printed on common mode filter 150. For example, when the impedance of the wound coil connected to second line 122 of differential line 120 is higher than the impedance of the wound coil connected to first line 121, first external terminal 51 of first varistor element Z1 is connected to first line 121 via first land electrode 141, and second external terminal 52 of second varistor element Z2, which has a larger electrostatic capacitance than first varistor element Z1, is connected to second line 122 via second land electrode 142. With this, the imbalance of differential line 120 in differential communication device 100 is inhibited, and the degradation of communication quality can be inhibited.

When the impedance of the wound coil connected to first line 121 is higher than the impedance of the wound coil connected to second line 122, it is appropriate to connect first external terminal 51 of first varistor element Z1 to second line 122, and connect second external terminal 52 of second varistor element Z2 to first line 121.

### Advantageous Effects

The advantageous effects of varistor component 1 having the above configuration will be described with reference to FIG. 6 through FIG. 14.

FIG. 6 illustrates a differential communication device for measurement and evaluation.

The differential communication device for measurement and evaluation includes, mounted on substrate 105 on which first line 121, second line 122, and ground line 131 (not illustrated) are provided, connector 110, varistor component 1, common mode filter 150, and transceiver IC 160.

A coaxial connector having a characteristic impedance of 50Ω is used as connector 110. Wiring patterns having a characteristic impedance of 50Ω are formed as first line 121 and second line 122.

In the present embodiment, a network analyzer is connected to connector 110, and the communication quality of the differential communication device is evaluated by measuring mode conversion characteristic Sdc11 (dB). Sdc11 is a reflection characteristic that indicates the amount of common mode component converted to differential mode component, and a smaller value indicates higher communication quality.

To confirm the advantageous effect of varistor component 1 according to the present embodiment, a similar evaluation will be performed on varistor component 501 according to a comparative example.

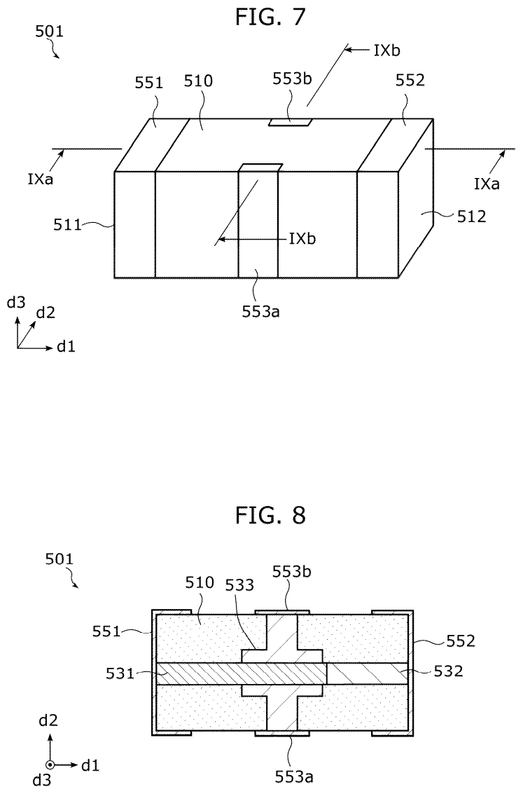

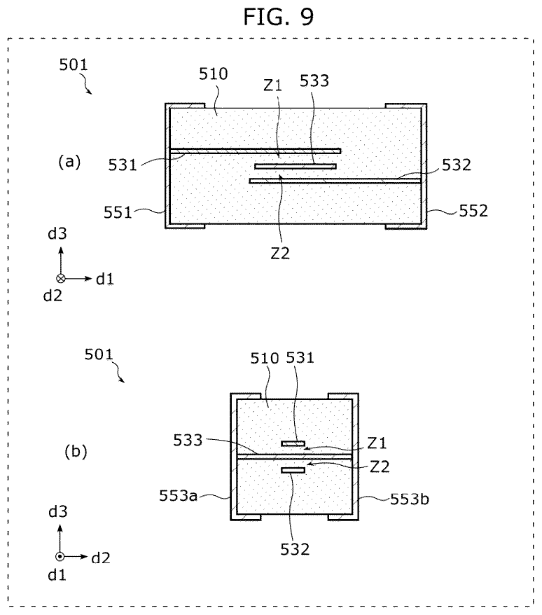

FIG. 7 is perspective view illustrating varistor component 501 according to a comparative example. FIG. 8 is a see-through view illustrating the internal electrodes and the like of varistor component 501 according to the comparative example in a view facing the top surface. FIG. 9 is a cross-sectional view of varistor component 501 according to the comparative example. In FIG. 9, (a) is a view of varistor component 501 as seen from line IXa-IXa illustrated in FIG. 7, and (b) is a view of varistor component 501 as seen from line IXb-IXb illustrated in FIG. 7.

Varistor component 501 according to the comparative example illustrated in FIG. 7 through FIG. 9 includes varistor-material sintered body 510, a plurality of external terminals provided outside varistor-material sintered body 510, and a plurality of internal electrodes provided inside varistor-material sintered body 510.

The plurality of external terminals include first external terminal 551, second external terminal 552, and third external terminals 553a and 553b. The plurality of internal electrodes include first internal electrode 531, second internal electrode 532, and third internal electrode 533.

In varistor component 501 according to the comparative example, the opposing surface area of first internal electrode 531 and third internal electrode 533 is the same as the opposing surface area of second internal electrode 532 and third internal electrode 533, and thus electrostatic capacitance C1 of first varistor element Z1 and electrostatic capacitance C2 of second varistor element Z2 are the same (C1=C2). In the comparative example, an evaluation was performed on a differential communication device using this varistor component 501.

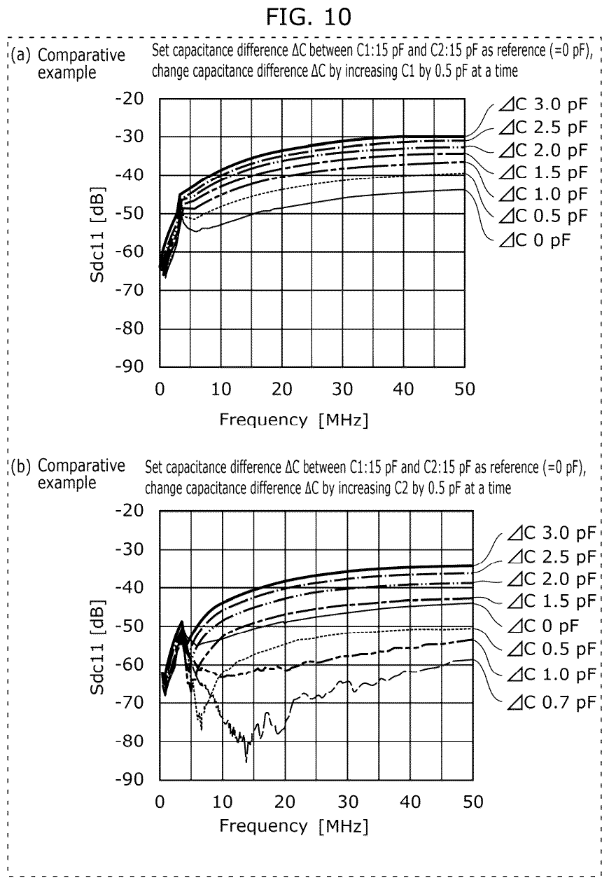

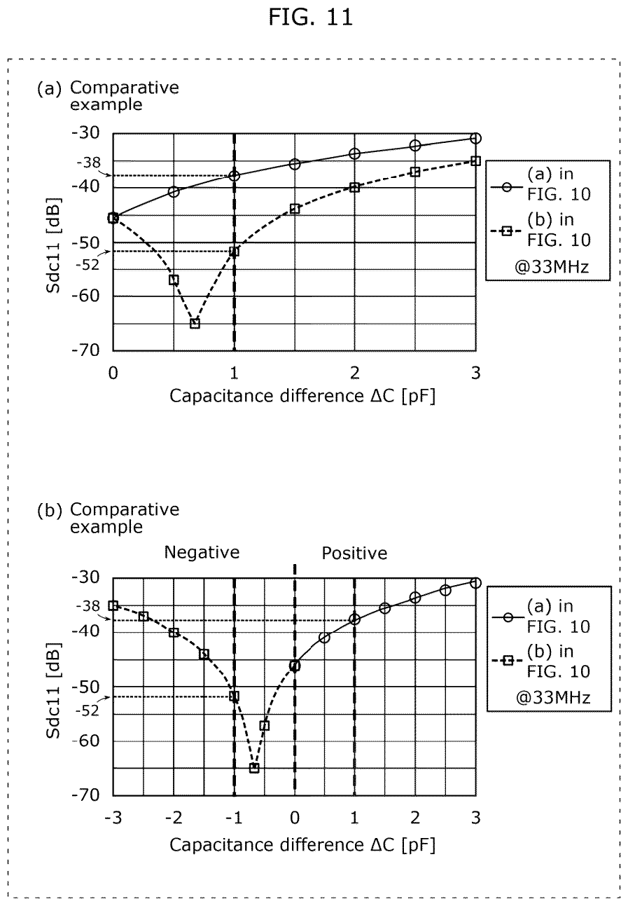

FIG. 10 illustrates the relationship between the electrostatic capacitance of varistor component 501 according to the comparative example and Sdc11 of the differential communication device.

In (a) in FIG. 10, electrostatic capacitance C1 of first varistor element Z1 is set to 15 pF, electrostatic capacitance C2 of second varistor element Z2 is set to 15 pF, and capacitance difference ΔC at this time is used as a reference (=0 pF), and an example is illustrated in which capacitance difference ΔC is changed by increasing electrostatic capacitance C1 by 0.5 pF at a time. As illustrated in (a) in FIG. 10, as capacitance difference ΔC increases, the value of Sdc11 increases. The electrostatic capacitance was varied and evaluated in order to investigate the influence of manufacturing variations in electrostatic capacitance on Sdc11.

In (b) in FIG. 10, electrostatic capacitance C1 of first varistor element Z1 is set to 15 pF, electrostatic capacitance C2 of second varistor element Z2 is set to 15 pF, and capacitance difference ΔC at this time is used as a reference (=0 pF), and an example is illustrated in which capacitance difference ΔC is changed by increasing electrostatic capacitance C2 by 0.5 pF at a time. As illustrated in (b) in FIG. 10, the value of Sdc11 is minimized when capacitance difference ΔC is 0.7 pF, but when capacitance difference ΔC exceeds 0.7 pF, the value of Sdc11 increases.

FIG. 11 illustrates the relationship between the electrostatic capacitance of varistor component 501 according to the comparative example and Sdc11 of the differential communication device at a predetermined frequency. FIG. 11 illustrates an example in which the predetermined frequency is 33 MHZ.

In FIG. 11, (a) is a diagram in which capacitance difference ΔC illustrated in FIG. 10 is represented on the horizontal axis and Sdc11 is represented on the vertical axis. In FIG. 11, (b) is a diagram in which capacitance difference ΔC on the horizontal axis of (a) in FIG. 11 is represented with positive and negative signs. More specifically, the horizontal axis in (b) in FIG. 11 is represented such that as electrostatic capacitance C1 increases, positive capacitance difference ΔC increases, and as electrostatic capacitance C2 increases, negative capacitance difference ΔC increases. As illustrated in (b) in FIG. 11, in the comparative example, when capacitance difference ΔC is −1 pF, Sdc11 is −52 dB, which is a small value, but when capacitance difference ΔC is +1 pF, Sdc11 is −38 dB, which is a large value. Therefore, when varistor component 501 according to the comparative example is used in a differential communication device, the communication quality of the differential communication device may degrade due to manufacturing variations of varistor component 501.

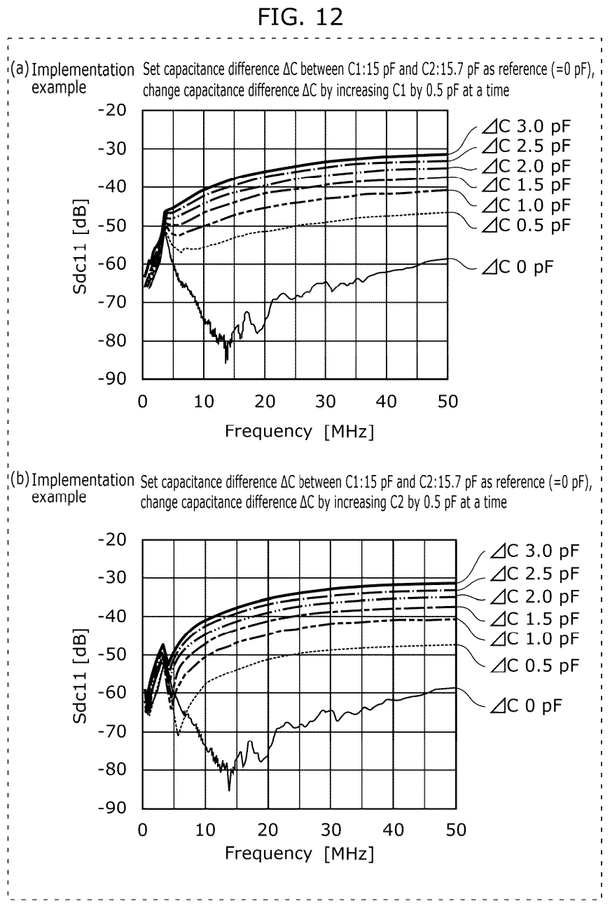

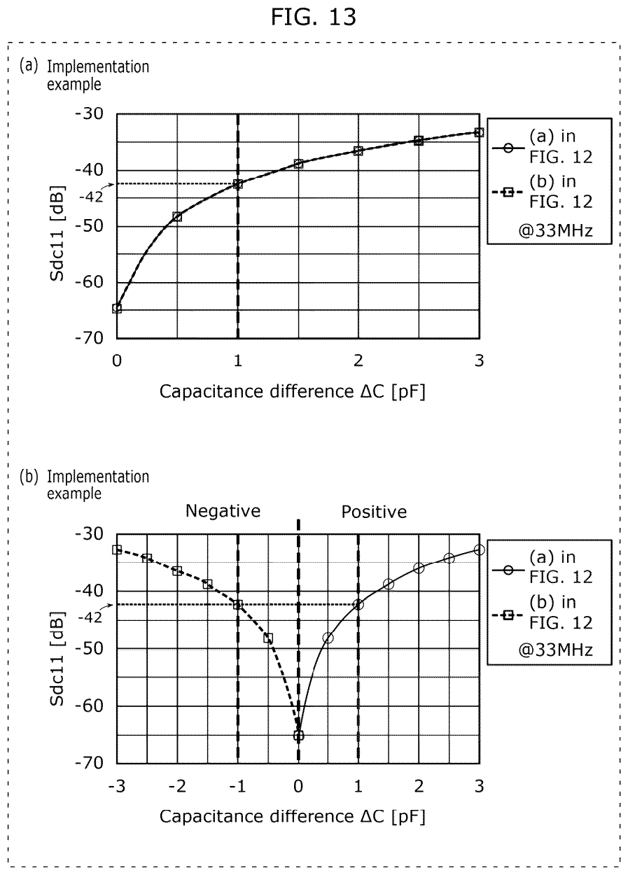

FIG. 12 illustrates the relationship between the electrostatic capacitance of varistor component 1 according to an implementation example, which is one example of an embodiment according to the present disclosure, and Sdc11 of differential communication device 100.

In (a) in FIG. 12, electrostatic capacitance C1 of first varistor element Z1 is set to 15 pF, electrostatic capacitance C2 of second varistor element Z2 is set to 15.7 pF, and capacitance difference ΔC at this time is used as a reference (=0 pF), and an example is illustrated in which capacitance difference ΔC is changed by increasing electrostatic capacitance C1 by 0.5 pF at a time. As illustrated in (a) in FIG. 12, as capacitance difference ΔC increases, the value of Sdc11 increases.

In (b) in FIG. 12, electrostatic capacitance C1 of first varistor element Z1 is set to 15 pF, electrostatic capacitance C2 of second varistor element Z2 is set to 15.7 pF, and capacitance difference ΔC at this time is used as a reference (=0 pF), and an example is illustrated in which capacitance difference ΔC is changed by increasing electrostatic capacitance C2 by 0.5 pF at a time. As illustrated in (b) in FIG. 12, as capacitance difference ΔC increases, the value of Sdc11 increases.

FIG. 13 illustrates the relationship between the electrostatic capacitance of varistor component 1 according to the implementation example and Sdc11 of differential communication device 100 at a predetermined frequency. FIG. 13 illustrates an example in which the predetermined frequency is 33 MHZ.

In FIG. 13, (a) is a diagram in which capacitance difference ΔC illustrated in FIG. 12 is represented on the horizontal axis and Sdc11 is represented on the vertical axis. In FIG. 13, (b) is a diagram in which capacitance difference ΔC on the horizontal axis of (a) in FIG. 13 is represented with positive and negative signs. More specifically, the horizontal axis in (b) in FIG. 13 is represented such that as electrostatic capacitance C1 increases, positive capacitance difference ΔC increases, and as electrostatic capacitance C2 increases, negative capacitance difference ΔC increases. As illustrated in (b) in FIG. 13, in the implementation example, when capacitance difference ΔC is −1 pF, the value of Sdc11 is −42 dB, and when capacitance difference ΔC is +1 pF, the value of Sdc11 is also −42 dB. When comparing the maximum values of Sdc11, the value of Sdc11 in the implementation example is smaller than the value of Sdc11 in the comparative example.

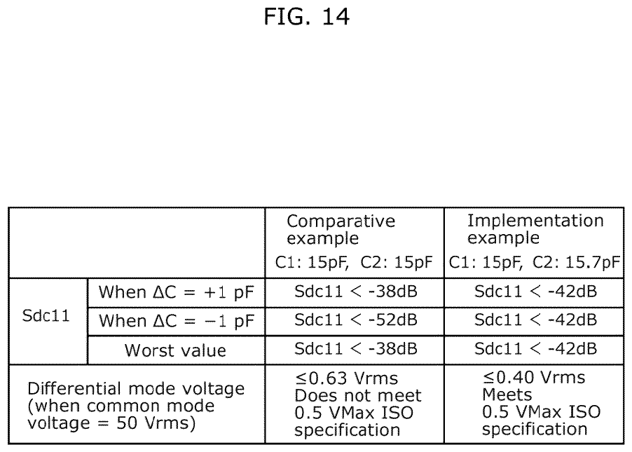

FIG. 14 compares Sdc11 of the differential communication device in the comparative example and the implementation example.

FIG. 14 illustrates values of Sdc11 when capacitance difference ΔC is ±1 pF, and the corresponding differential mode voltage (voltage converted from common mode to differential mode).

As illustrated in FIG. 14, the worst value of Sdc11 in the comparative example is −38 dB, and the worst value of Sdc11 in the implementation example is −42 dB. Comparing the worst values of Sdc11, the value of Sdc11 in the implementation example is smaller than the value in the comparative example.

For example, the common mode voltage input during immunity tests such as Bulk Current Injection (BCI) tests is approximately 50 Vrms (70 Vpp, 33 MHZ). As a result of Sdc11 decreasing from −38 dB or less in the comparative example to −42 dB or less in the implementation example as described above, the differential mode voltage improves from 0.63 Vrms or less to 0.40 Vrms or less. Therefore, even with manufacturing variations in electrostatic capacitance of approximately ±1 pF, the differential mode voltage of 0.5 Vmax stipulated by ISO 11898-2:2016 (CAN-FD physical layer standard) is satisfied in the implementation example. Accordingly, differential communication device 100 characterized by good immunity tolerance (communication quality) can be realized.

Note that the relationship between differential mode voltage Vdiff, common mode voltage Vcm, and Sdc11 is expressed by Equation 1 below.

$$Sdc 11 ( d B ) = 20 log ( Vdiff / Vcm ) \qquad ( Equation l )$$

Transforming Equation 1 yields Vdiff=Vcm×10\hat{ }(Sdc11/20). The differential mode voltages (0.63 Vrms and 0.40 Vrms) mentioned earlier are derived from the above equation.

In the implementation example, the electrostatic capacitance of second varistor element Z2 when +1 pF satisfies the above evaluation criteria is 16.7 pF, which is 1.113 times the electrostatic capacitance (15 pF) of first varistor element Z1. Therefore, in order to satisfy the above evaluation criteria, it is desirable that electrostatic capacitance C2 of second varistor element Z2 is less than or equal to 1.12 times electrostatic capacitance C1 of first varistor element Z1.

Note that manufacturing variations in electrostatic capacitance occur due to factors such as misalignment in the ceramic stacking process and variations in the thickness of the stacked sheets. Products with small electrostatic capacitance C1 and electrostatic capacitance C2 tend to have smaller capacitance difference ΔC resulting from manufacturing variations, and also tend to have a smaller value of Sdc11. However, in general, the electrostatic capacitance of a varistor is closely related to the effect of electrostatic countermeasures, and if the electrostatic capacitance is small, the electrostatic absorption characteristics and resistance to static electricity decrease. With varistor component 1 according to the present embodiment, since the electrostatic capacitance is not made small, the effect of electrostatic countermeasures can be maintained.

Varistor component 1 according to the present embodiment includes first varistor element Z1 and second varistor element Z2, and electrostatic capacitance C1 of first varistor element Z1 and electrostatic capacitance C2 of second varistor element Z2 are different.

With this, when there is an imbalance in differential line 120 of differential communication device 100, that imbalance can be inhibited, and the degradation of communication quality of differential communication device 100 can be inhibited.

### Variation 1 of Embodiment

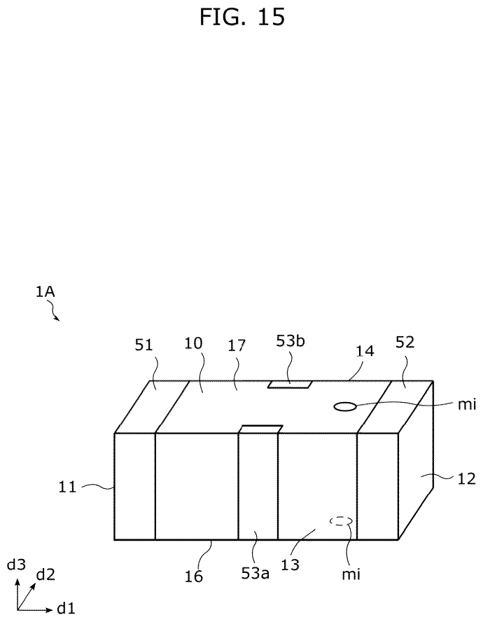

Varistor component 1A according to Variation 1 of an embodiment of the present disclosure will be described with reference to FIG. 15. In Variation 1, an example in which varistor component 1A includes identification mark mi will be given.

FIG. 15 illustrates varistor component 1A according to Variation 1 of an embodiment of the present disclosure.

Varistor component 1A illustrated in FIG. 15 includes identification mark mi for distinguishing between first external terminal 51 and second external terminal 52. Identification mark mi is, for example, a recessed indentation formed in the ceramic stacking process. Identification mark mi is, for example, formed near second external terminal 52 of second varistor element Z2 having a large electrostatic capacitance. Identification mark mi is provided on both of bottom surface 16 and top surface 17, but the present disclosure is not limited to this example. For example, identification mark mi may be provided on at least one of bottom surface 16 or top surface 17. When varistor component 1A is packaged by taping, it may be taped in a state where the orientation in first direction d1 and the orientation in third direction d3 are predetermined so that identification mark mi is visible.

### Variation 2 of Embodiment

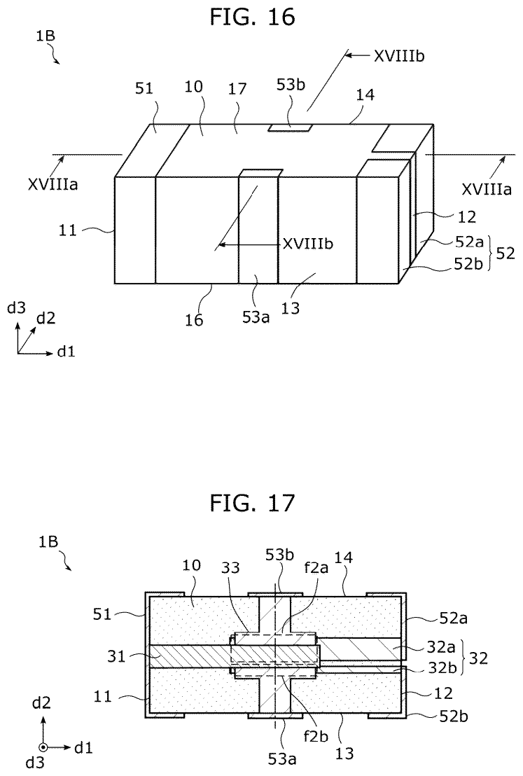

The configuration of varistor component 1B according to Variation 2 of an embodiment of the present disclosure will be described with reference to FIG. 16 through FIG. 19. In Variation 2, an example in which second internal electrode 32 includes second main electrode 32a and second auxiliary electrode 32b, and second external terminal 52 includes second main terminal 52a and second auxiliary terminal 52b will be given.

FIG. 16 is perspective view illustrating varistor component 1B according to Variation 2 of an embodiment of the present disclosure. Note that in FIG. 16, illustration of the thickness of the external terminals is omitted.

Varistor component 1B illustrated in FIG. 16 includes varistor-material sintered body 10, a plurality of external terminals provided outside varistor-material sintered body 10, and a plurality of internal electrodes provided inside varistor-material sintered body 10.

The plurality of external terminals include first external terminal 51, second external terminal 52, and third external terminals 53a and 53b. First external terminal 51, the second external terminal, and third external terminals 53a and 53b are not electrically connected to each other.

First external terminal 51 and third external terminals 53a and 53b are the same as in the above embodiment. Note that in Variation 2, since the difference between first external terminal 51 and second external terminal 52 can be distinguished by their shape, the length of second external terminal 52 in first direction d1 is the same as the length of first external terminal 51 in first direction d1.

In Variation 2, second external terminal 52 includes second main terminal 52a and second auxiliary terminal 52b. Second main terminal 52a and second auxiliary terminal 52b are not electrically connected to each other inside varistor component 1B.

Second main terminal 52a is provided on second side surface 12. Second main terminal 52a is a terminal on one end of second varistor element Z2 and is connected to second line 122.

Second auxiliary terminal 52b is provided in a region on second side surface 12 that is different from the region of second main terminal 52a. Second auxiliary terminal 52b is a terminal on one end of second varistor element Z2. Depending on the application, second auxiliary terminal 52b is connected or not connected to second line 122. In the present variation, an example in which second auxiliary terminal 52b is connected to second line 122 will be given.

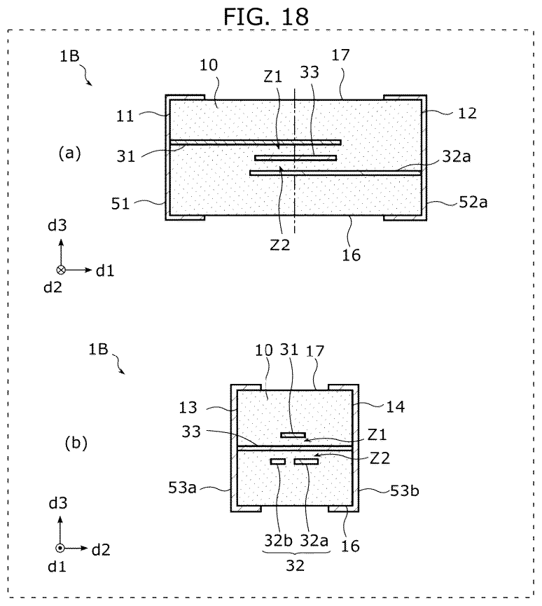

FIG. 17 is a see-through view illustrating the internal electrodes and the like of varistor component 1B in a view facing top surface 17. FIG. 18 is a cross-sectional view of varistor component 1B. In FIG. 18, (a) is a view of varistor component 1B as seen from line XVIIIa-XVIIIa illustrated in FIG. 16, and (b) is a view of varistor component 1B as seen from line XVIIIb-XVIIIb illustrated in FIG. 16.

The plurality of internal electrodes of varistor component 1B illustrated in FIG. 17 and FIG. 18 include first internal electrode 31, second internal electrode 32, and third internal electrode 33.

First internal electrode 31 and third internal electrode 33 are the same as in the above embodiment.

In Variation 2, second internal electrode 32 includes second main electrode 32a and second auxiliary electrode 32b. Second main electrode 32a and second auxiliary electrode 32b are not electrically connected to each other inside varistor component 1B.

Second main electrode 32a is connected to second main terminal 52a at second side surface 12, and second auxiliary electrode 32b is connected to second auxiliary terminal 52b at second side surface 12. Second main electrode 32a and second auxiliary electrode 32b are formed on the same ceramic layer. Each of second main electrode 32a and second auxiliary electrode 32b is provided parallel to bottom surface 16 or top surface 17.

Second main electrode 32a and second auxiliary electrode 32b are arranged closer to bottom surface 16 than third internal electrode 33 is. Stated differently, second main electrode 32a and second auxiliary electrode 32b are provided on one side of third internal electrode 33 and first internal electrode 31 is provided on the opposite side of third internal electrode 33, and at least a portion of second main electrode 32a and at least a portion of second auxiliary electrode 32b oppose third internal electrode 33. For example, second main electrode 32a and second auxiliary electrode 32b are each rectangular when viewed from third direction d3, and extend from second side surface 12 toward first side surface 11 beyond opposing regions f2a and f2b in which second main electrode 32a and second auxiliary electrode 32b oppose third internal electrode 33, respectively.

In Variation 2, the value of electrostatic capacitance C2 of second varistor element Z2 is a value that varies depending on the opposing surface area of opposing region f2a in which second main electrode 32a and third internal electrode 33 oppose each other, and the opposing surface area of opposing region f2b in which second auxiliary electrode 32b and third internal electrode 33 oppose each other. Electrostatic capacitance C2 is the sum of electrostatic capacitance C2a formed by second main electrode 32a and third internal electrode 33, and electrostatic capacitance C2b formed by second auxiliary electrode 32b and third internal electrode 33 (C2=C2a+C2b).

In Variation 2, the opposing surface area of second internal electrode 32 and third internal electrode 33 is larger than the opposing surface area of first internal electrode 31 and third internal electrode 33, and electrostatic capacitance C2 of second varistor element Z2 is greater than electrostatic capacitance C1 of first varistor element Z1 (C1<C2).

Stated differently, the total electrostatic capacitance of electrostatic capacitance C2a and electrostatic capacitance C2b is greater than electrostatic capacitance C1 (C1< (C2a+C2b)). Note that electrostatic capacitance C2a is the same as electrostatic capacitance C1 (C1=C2a), and electrostatic capacitance C2b is smaller than electrostatic capacitance C2a (C2a>C2b).

In Variation 2, the opposing surface area between second main electrode 32a and third internal electrode 33 is the same as the opposing surface area between first internal electrode 31 and third internal electrode 33. The opposing surface area between second auxiliary electrode 32b and third internal electrode 33 is smaller than the opposing surface area between second main electrode 32a and third internal electrode 33.

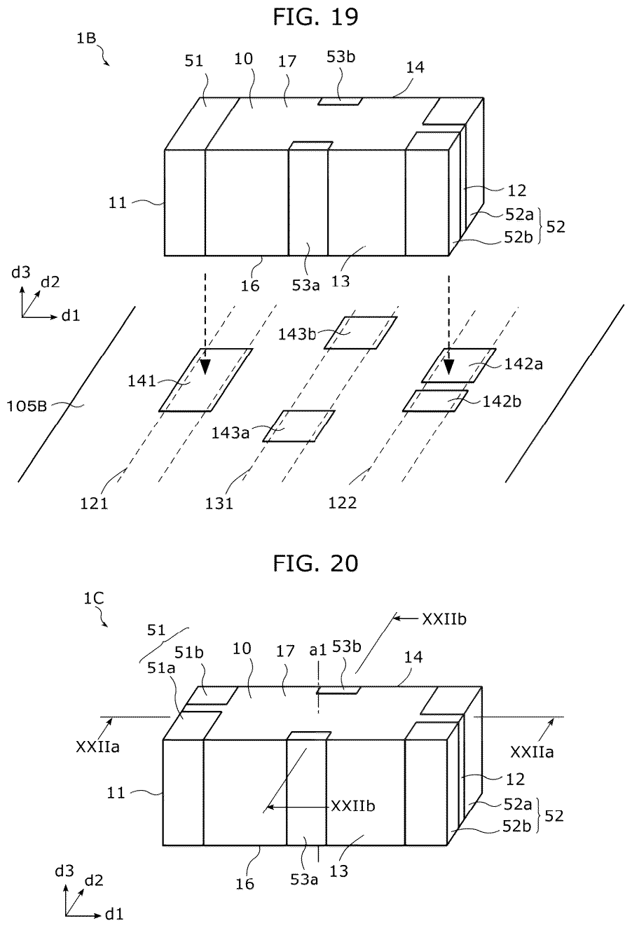

FIG. 19 illustrates varistor component 1B and substrate 105B on which varistor component 1B is mounted.

As illustrated in FIG. 19, first line 121, second line 122, and ground line 131 are formed on substrate 105B. Substrate 105B is also provided with first land electrode 141 for connecting first line 121 and first external terminal 51, and third land electrodes 143a and 143b for connecting ground line 131 and third external terminals 53a and 53b. In Variation 2, substrate 105B includes second main land electrode 142a for connecting second line 122 and second main terminal 52a, and second auxiliary land electrode 142b for connecting second line 122 and second auxiliary terminal 52b.

When mounting varistor component 1B on substrate 105B, first external terminal 51, second main terminal 52a, second auxiliary terminal 52b, and third external terminals 53a and 53b are respectively connected to first land electrode 141, second main land electrode 142a, second auxiliary land electrode 142b, and third land electrodes 143a and 143b via solder.

For example, when the impedance of the wound coil connected to second line 122 of differential line 120 is higher than the impedance of the wound coil connected to first line 121, first external terminal 51 is connected to first line 121 via first land electrode 141, second main terminal 52a is connected to second line 122 via second main land electrode 142a, and second auxiliary terminal 52b is connected to second line 122 via second auxiliary land electrode 142b. With this, the imbalance of differential line 120 in differential communication device 100 is inhibited, and the degradation of communication quality can be inhibited.

Note that when the impedances of the wound coils connected to first line 121 and second line 122 are the same, that is, when no imbalance occurs in differential line 120, it is not necessary to form second auxiliary land electrode 142b and connect second auxiliary terminal 52b to second line 122.

Variation 2 provides varistor component 1B that is applicable to both cases where an imbalance occurs and does not occur in differential line 120. Moreover, with Variation 2, it becomes unnecessary to add a capacitive element different from the varistor component to differential communication device 100, thereby reducing the number of components of differential communication device 100. Moreover, it becomes unnecessary to increase the width and length of the wiring patterns of differential line 120 of differential communication device 100 to add capacitance, thereby reducing the size of differential communication device 100.

### Variation 3 of Embodiment

The configuration of varistor component 1C according to Variation 3 of an embodiment of the present disclosure will be described with reference to FIG. 20 through FIG. 23. In Variation 3, an example in which first internal electrode 31 includes first main electrode 31a and first auxiliary electrode 31b, and first external terminal 51 includes first main terminal 51a and first auxiliary terminal 51b, in addition to the configuration of Variation 2, will be given.

FIG. 20 is perspective view illustrating varistor component 1C according to Variation 3 of an embodiment of the present disclosure. Note that in FIG. 20, illustration of the thickness of the external terminals is omitted.

Varistor component 1C illustrated in FIG. 20 includes varistor-material sintered body 10, a plurality of external terminals provided outside varistor-material sintered body 10, and a plurality of internal electrodes provided inside varistor-material sintered body 10.

The plurality of external terminals include first external terminal 51, second external terminal 52, and third external terminals 53a and 53b. First external terminal 51, the second external terminal, and third external terminals 53a and 53b are not electrically connected to each other.

Third external terminals 53a and 53b are the same as in the above embodiment, and second external terminal 52 is the same as in Variation 2.

In Variation 3, first external terminal 51 includes first main terminal 51a and first auxiliary terminal 51b. First main terminal 51a and first auxiliary terminal 51b are not electrically connected to each other inside varistor component 1C.

First main terminal 51a is provided on first side surface 11. First main terminal 51a is a terminal on one end of first varistor element Z1 and is connected to first line 121.

First auxiliary terminal 51b is provided in a region on first side surface 11 that is different from the region of first main terminal 51a. First auxiliary terminal 51b is a terminal on one end of first varistor element Z1. Depending on the application, first auxiliary terminal 51b is connected or not connected to first line 121. In the present variation, an example in which first main terminal 51a and first auxiliary terminal 51b are connected to first line 121, second main terminal 52a is connected to second line 122, and second auxiliary terminal 52b is not connected to second line 122 will be given.

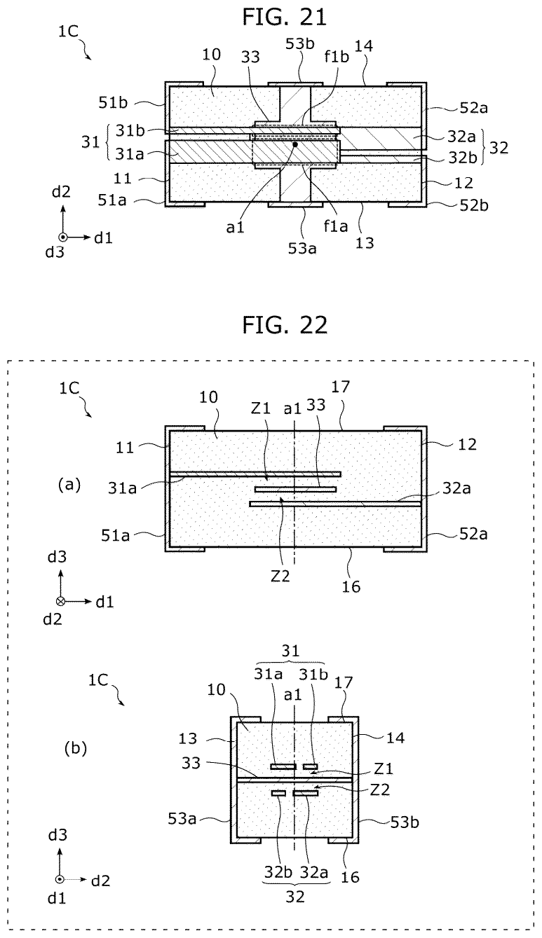

FIG. 21 is a see-through view illustrating the internal electrodes and the like of varistor component 1C in a view facing top surface 17. FIG. 22 is a cross-sectional view of varistor component 1C. In FIG. 22, (a) is a view of varistor component 1C as seen from line XXIIa-XXIIa illustrated in FIG. 20, and (b) is a view of varistor component 1C as seen from line XXIIb-XXIIb illustrated in FIG. 20.

The plurality of internal electrodes of varistor component 1C illustrated in FIG. 21 and FIG. 22 include first internal electrode 31, second internal electrode 32, and third internal electrode 33.

Third internal electrode 33 is the same as in the embodiment, and second internal electrode 32 is the same as in Variation 2.

In Variation 3, first internal electrode 31 includes first main electrode 31a and first auxiliary electrode 31b. First main electrode 31a and first auxiliary electrode 31b are not electrically connected to each other inside varistor component 1C.

First main electrode 31a is connected to first main terminal 51a at first side surface 11, and first auxiliary electrode 31b is connected to first auxiliary terminal 51b at first side surface 11. First main electrode 31a and first auxiliary electrode 31b are formed on the same ceramic layer. Each of first main electrode 31a and first auxiliary electrode 31b is provided parallel to bottom surface 16 or top surface 17.

First main electrode 31a and first auxiliary electrode 31b are arranged closer to top surface 17 than third internal electrode 33 is. Stated differently, first main electrode 31a and first auxiliary electrode 31b are provided on one side of third internal electrode 33 and second internal electrode 32 is provided on the opposite side of third internal electrode 33, and at least a portion of first main electrode 31a and at least a portion of first auxiliary electrode 31b oppose third internal electrode 33. For example, first main electrode 31a and first auxiliary electrode 31b are each rectangular when viewed from third direction d3, and extend from first side surface 11 toward second side surface 12 beyond opposing regions f1a and f1b in which first main electrode 31a and first auxiliary electrode 31b oppose third internal electrode 33, respectively.

In Variation 3, the value of electrostatic capacitance C1X of first varistor element Z1 is a value that varies depending on the opposing surface area of opposing region f1a in which first main electrode 31a and third internal electrode 33 oppose each other, and the opposing surface area of opposing region f1b in which first auxiliary electrode 31b and third internal electrode 33 oppose each other. Electrostatic capacitance C1X is the sum of electrostatic capacitance C1a formed by first main electrode 31a and third internal electrode 33, and electrostatic capacitance C1b formed by first auxiliary electrode 31b and third internal electrode 33 (C1X=C1a+C1b).

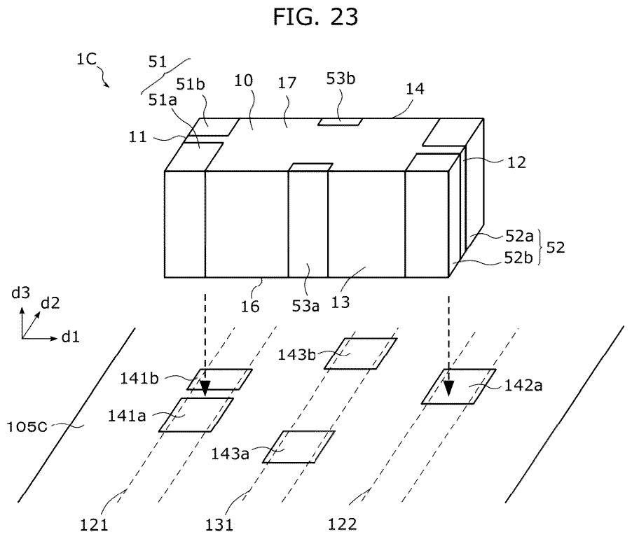

In Variation 3, the opposing surface area of second internal electrode 32 and third internal electrode 33 is the same as the opposing surface area of first internal electrode 31 and third internal electrode 33, but when varistor component 1C is mounted on substrate 105C (refer to FIG. 23), electrostatic capacitance C1X on the first varistor element Z1 side becomes greater than electrostatic capacitance C2a on the second varistor element Z2 side (C1X>C2a).

More specifically, the total electrostatic capacitance of electrostatic capacitance C1a and electrostatic capacitance C1b is greater than electrostatic capacitance C2a ((C1a+C1b)>C2a). Note that electrostatic capacitance C1a is the same as electrostatic capacitance C2a (C1a=C2a), and electrostatic capacitance C1b is smaller than electrostatic capacitance C1a (C1a>C1b).

In Variation 3, the opposing surface area between first main electrode 31a and third internal electrode 33 is the same as the opposing surface area between second main electrode 32a and third internal electrode 33. The opposing surface area between first auxiliary electrode 31b and third internal electrode 33 is smaller than the opposing surface area between first main electrode 31a and third internal electrode 33.

In Variation 3, in a view of varistor component 1C along central axis a1 passing through the center of bottom surface 16 and the center of top surface 17, first main electrode 31a and second main electrode 32a are point-symmetrical with respect to central axis a1, and first auxiliary electrode 31b and second auxiliary electrode 32b are point-symmetrical with respect to central axis a1. In a view of varistor component 1C along central axis a1, first main terminal 51a and second main terminal 52a are point-symmetrical with respect to central axis a1, and first auxiliary terminal 51b and second auxiliary terminal 52b are point-symmetrical with respect to central axis a1. With this configuration, varistor component 1C can be mounted on substrate 105C without any problems even if the orientations of first external terminal 51 and second external terminal 52 are reversed. With this, the mounting process for mounting varistor component 1C on substrate 105C can be simplified.

Note that in Variation 3, although the difference between first external terminal 51 and second external terminal 52 cannot be distinguished by their shape, since varistor component 1C can be mounted on substrate 105C without any problems even if the orientations of first external terminal 51 and second external terminal 52 are reversed, the length of second external terminal 52 in first direction d1 is the same as the length of first external terminal 51 in first direction d1.

FIG. 23 illustrates varistor component 1C and substrate 105C on which varistor component 1C is mounted.

As illustrated in FIG. 23, first line 121, second line 122, and ground line 131 are formed on substrate 105C. Substrate 105C is provided with third land electrodes 143a and 143b for connecting ground line 131 and third external terminals 53a and 53b. In Variation 3, substrate 105C is provided with first main land electrode 141a for connecting first line 121 and first main terminal 51a, and first auxiliary land electrode 141b for connecting first line 121 and first auxiliary terminal 51b. Substrate 105C is provided with second main land electrode 142a for connecting second line 122 and second main terminal 52a. Note that second auxiliary land electrode 142b for connecting second line 122 and second auxiliary terminal 52b is not provided.

When mounting varistor component 1C on substrate 105C, first main terminal 51a, first auxiliary terminal 51b, second main terminal 52a, and third external terminals 53a and 53b are respectively connected to first main land electrode 141a, first auxiliary land electrode 141b, second main land electrode 142a, and third land electrodes 143a and 143b via solder.

For example, when the impedance of the wound coil connected to first line 121 of differential line 120 is higher than the impedance of the wound coil connected to second line 122, first main terminal 51a is connected to first line 121 via first main land electrode 141a, first auxiliary terminal 51b is connected to first line 121 via first auxiliary land electrode 141b, and second main terminal 52a is connected to second line 122 via second main land electrode 142a. With this, the imbalance of differential line 120 in differential communication device 100 is inhibited, and the degradation of communication quality can be inhibited.

Note that when the impedances of the wound coils connected to first line 121 and second line 122 are the same, that is, when no imbalance occurs in differential line 120, it is not necessary to form first auxiliary land electrode 141b and connect first auxiliary terminal 51b to first line 121. Alternatively, both first auxiliary land electrode 141b and second auxiliary land electrode 142b may be formed, first auxiliary terminal 51b may be connected to first line 121, and second auxiliary terminal 52b may be connected to second line 122.

Variation 3 provides varistor component 1C that is applicable to both cases where an imbalance occurs and does not occur in differential line 120. Moreover, with Variation 2, it becomes unnecessary to add a capacitive element different from the varistor component to differential communication device 100, thereby reducing the number of components of differential communication device 100. Moreover, it becomes unnecessary to increase the width and length of the wiring patterns of differential line 120 of differential communication device 100 to add capacitance, thereby reducing the size of differential communication device 100.

When the impedance of the wound coil connected to second line 122 is higher than the impedance of the wound coil connected to first line 121, it is appropriate to connect first main terminal 51a to first line 121, not connect first auxiliary terminal 51b to first line 121, and connect second main terminal 52a and second auxiliary terminal 52b to second line 122. Variation 3 provides varistor component 1C that is applicable regardless of whether the impedance is higher on the first line 121 side or the second line 122 side.

### SUMMARY

Varistor component 1 according to the present embodiment includes first varistor element Z1 and second varistor element Z2, and electrostatic capacitance C1 of first varistor element Z1 and electrostatic capacitance C2 of second varistor element Z2 are different.

In this way, by making electrostatic capacitance C1 of first varistor element Z1 and electrostatic capacitance C2 of second varistor element Z2 different, for example, when varistor component 1 is disposed on the differential line of differential communication device 100, the imbalance of the differential line can be inhibited. With this, the degradation of communication quality of differential communication device 100 can be inhibited.

Varistor component 1 includes varistor-material sintered body 10, and first internal electrode 31, second internal electrode 32, and third internal electrode 33 which are provided inside varistor-material sintered body 10. At least a portion of first internal electrode 31 opposes third internal electrode 33. At least a portion of second internal electrode 32 opposes third internal electrode 33. The value of electrostatic capacitance C1 of first varistor element Z1 is a value that varies depending on the opposing surface area of first internal electrode 31 and third internal electrode 33. The value of electrostatic capacitance C2 of second varistor element Z2 is a value that varies depending on the opposing surface area of second internal electrode 32 and third internal electrode 33. The opposing surface area between first internal electrode 31 and third internal electrode 33 may be different from the opposing surface area between second internal electrode 32 and third internal electrode 33.

With this configuration, electrostatic capacitance C1 of first varistor element Z1 and electrostatic capacitance C2 of second varistor element Z2 can be easily made different. Therefore, for example, when varistor component 1 is disposed on the differential line of differential communication device 100, the imbalance of the differential line can be inhibited. With this, the degradation of communication quality of differential communication device 100 can be inhibited.

Electrostatic capacitance C2 of second varistor element Z2 may be greater than electrostatic capacitance C1 of first varistor element Z1, and the opposing surface area of second internal electrode 32 and third internal electrode 33 may be larger than the opposing surface area of first internal electrode 31 and third internal electrode 33.

In this way, by making electrostatic capacitance C2 of second varistor element Z2 greater than electrostatic capacitance C1 of first varistor element Z1, for example, when varistor component 1 is disposed on the differential line of differential communication device 100, the imbalance of the differential line can be inhibited. With this, the degradation of communication quality of differential communication device 100 can be inhibited.

Varistor-material sintered body 10 includes bottom surface 16 and top surface 17 facing in opposite directions, and a plurality of side surfaces perpendicular to bottom surface 16 and top surface 17. The plurality of side surfaces include first side surface 11 and second side surface 12 facing in opposite directions, and third side surface 13 and fourth side surface 14 facing in opposite directions and perpendicular to first side surface 11 and bottom surface 16. Each of first internal electrode 31, second internal electrode 32, and third internal electrode 33 is provided parallel to bottom surface 16 or top surface 17. When a direction parallel to the opposite directions in which first side surface 11 and second side surface 12 face is defined as first direction d1, and a direction parallel to the opposite directions in which third side surface 13 and fourth side surface 14 face is defined as second direction d2, the width dimension of second internal electrode 32 in second direction d2 may be greater than the width dimension of first internal electrode 31 in second direction d2.

With this configuration, the opposing surface area between second internal electrode 32 and third internal electrode 33 can be made larger than the opposing surface area between first internal electrode 31 and third internal electrode 33 more easily. Therefore, electrostatic capacitance C2 of second varistor element Z2 can be made greater than electrostatic capacitance C1 of first varistor element Z1, and for example, when varistor component 1 is disposed on the differential line of differential communication device 100, the imbalance of the differential line can be inhibited. With this, the degradation of communication quality of differential communication device 100 can be inhibited.

Varistor component 1 further includes first external terminal 51 provided on first side surface 11, second external terminal 52 provided on second side surface 12, and third external terminals 53a and 53b provided on at least one of third side surface 13 or fourth side surface 14. First internal electrode 31 may be connected to first external terminal 51 at first side surface 11, second internal electrode 32 may be connected to second external terminal 52 at second side surface 12, and third internal electrode 33 may be connected to third external terminals 53a and 53b at at least one of third side surface 13 or fourth side surface 14.

In this way, by varistor component 1 including first external terminal 51, second external terminal 52, and third external terminals 53a and 53b, varistor component 1 can be appropriately disposed on the differential line of differential communication device 100, and the imbalance of the differential line can be inhibited. With this, the degradation of communication quality of differential communication device 100 can be inhibited.

First external terminal 51 is also provided on a portion of each of bottom surface 16, top surface 17, third side surface 13, and fourth side surface 14 so as to connect to the portion of first external terminal 51 on first side surface 11. Second external terminal 52 is also provided on a portion of each of bottom surface 16, top surface 17, third side surface 13, and fourth side surface 14, in regions other than regions where first external terminal 51 is provided, so as to connect to the portion of second external terminal 52 on second side surface 12. On each of bottom surface 16, top surface 17, third side surface 13, and fourth side surface 14, the length of second external terminal 52 in first direction d1 may be longer than the length of first external terminal 51 in first direction d1.

With this configuration, first external terminal 51 and second external terminal 52 can be easily distinguished. Therefore, varistor component 1 can be disposed on the differential line of differential communication device 100 in an appropriate orientation, and the imbalance of the differential line can be inhibited. With this, the degradation of communication quality of differential communication device 100 can be inhibited.

Varistor component 1A further includes identification mark mi for distinguishing between first external terminal 51 and second external terminal 52. Identification mark mi may be provided on at least one of bottom surface 16 or top surface 17.

With this configuration, first external terminal 51 and second external terminal 52 can be easily distinguished. Therefore, varistor component 1 can be disposed on the differential line of differential communication device 100 in an appropriate orientation, and the imbalance of the differential line can be inhibited. With this, the degradation of communication quality of differential communication device 100 can be inhibited.

Second internal electrode 32 includes second main electrode 32a and second auxiliary electrode 32b that are not connected to each other. Second external terminal 52 includes second main terminal 52a and second auxiliary terminal 52b that are not connected to each other. Second main electrode 32a is connected to second main terminal 52a. Second auxiliary electrode 32b is connected to second auxiliary terminal 52b. Electrostatic capacitance C2a formed by second main electrode 32a and third internal electrode 33 may be the same as electrostatic capacitance C1 formed by first internal electrode 31 and third internal electrode 33.

This configuration provides varistor component 1B that is applicable to both cases where an imbalance occurs and does not occur in the differential line of differential communication device 100.

The opposing surface area between second main electrode 32a and third internal electrode 33 may be the same as the opposing surface area between first internal electrode 31 and third internal electrode 33, and the opposing surface area between second auxiliary electrode 32b and third internal electrode 33 may be smaller than the opposing surface area between second main electrode 32a and third internal electrode 33.

This configuration makes it possible to make fine adjustments to electrostatic capacitance C2. This configuration makes it possible to easily provide varistor component 1B that is applicable to both cases where an imbalance occurs and does not occur in the differential line of differential communication device 100.

Electrostatic capacitance C2 of second varistor element Z2 may be less than or equal to 1.12 times electrostatic capacitance C1 of first varistor element Z1.

In this way, by making electrostatic capacitance C2 of second varistor element Z2 less than or equal to 1.12 times electrostatic capacitance C1 of first varistor element Z1, for example, when varistor component 1 is disposed on the differential line of differential communication device 100, the imbalance of the differential line can be inhibited. With this, the degradation of communication quality of differential communication device 100 can be inhibited.

Varistor component 1C according to the present embodiment is a varistor component that includes first varistor element Z1 and second varistor element Z2. Varistor component 1C includes: varistor-material sintered body 10; first internal electrode 31, second internal electrode 32, and third internal electrode 33 provided inside varistor-material sintered body 10; first external terminal 51 connected to first internal electrode 31; second external terminal 52 connected to second internal electrode 32; and third external terminals 53a and 53b connected to third internal electrode 33. First internal electrode 31 includes first main electrode 31a and first auxiliary electrode 31b that are not connected to each other. Second internal electrode 32 includes second main electrode 32a and second auxiliary electrode 32b that are not connected to each other. First external terminal 51 includes first main terminal 51a and first auxiliary terminal 51b that are not connected to each other. Second external terminal 52 includes second main terminal 52a and second auxiliary terminal 52b that are not connected to each other. First main electrode 31a is connected to first main terminal 51a, first auxiliary electrode 31b is connected to first auxiliary terminal 51b, second main electrode 32a is connected to second main terminal 52a, and second auxiliary electrode 32b is connected to second auxiliary terminal 52b. At least a portion of first main electrode 31a and at least a portion of first auxiliary electrode 31b oppose third internal electrode 33. At least a portion of second main electrode 32a and at least a portion of second auxiliary electrode 32b oppose third internal electrode 33. Electrostatic capacitance C1a formed by first main electrode 31a and third internal electrode 33 is the same as electrostatic capacitance C2a formed by second main electrode 32a and third internal electrode 33. Electrostatic capacitance C1b formed by first auxiliary electrode 31b and third internal electrode 33 is the same as electrostatic capacitance C2b formed by second auxiliary electrode 32b and third internal electrode 33.

This configuration provides varistor component 1C that is applicable to both cases where an imbalance occurs and does not occur in the differential line of differential communication device 100, for example.

Varistor-material sintered body 10 includes bottom surface 16 and top surface 17 facing in opposite directions, and a plurality of side surfaces perpendicular to bottom surface 16 and top surface 17. In a view of varistor component 1C along central axis a1 passing through the center of bottom surface 16 and the center of top surface 17, first main electrode 31a and second main electrode 32a may be point-symmetrical with respect to central axis a1, and first auxiliary electrode 31b and second auxiliary electrode 32b may be point-symmetrical with respect to central axis a1.

With this configuration, varistor component 1C can be mounted on substrate 105C without any problems even if the orientations of first external terminal 51 and second external terminal 52 are reversed. With this, the mounting process for mounting varistor component 1C on substrate 105C can be simplified.

Differential communication device 100 according to the present embodiment includes transceiver IC 160, common mode filter 150 connected to transceiver IC 160, and varistor component 1 connected to common mode filter 150.

This configuration makes it possible to inhibit the imbalance of differential line 120 in differential communication device 100. With this, differential communication device 100 that can inhibit the degradation of communication quality can be provided.

Differential communication device 100 according to the present embodiment includes substrate 105 on which differential line 120 including first line 121 and second line 122 is provided, transceiver IC 160 mounted on substrate 105, common mode filter 150 mounted on substrate 105 and connected to transceiver IC 160, and varistor component 1 mounted on substrate 105 and connected to common mode filter 150.

This configuration makes it possible to inhibit the imbalance of differential line 120 in differential communication device 100. With this, differential communication device 100 that can inhibit the degradation of communication quality can be provided.

Differential communication device 100 according to the present embodiment includes substrate 105B on which differential line 120 including first line 121 and second line 122 is provided, transceiver IC 160 mounted on substrate 105B, common mode filter 150 mounted on substrate 105B and connected to transceiver IC 160, and varistor component 1B mounted on substrate 105B and connected to common mode filter 150. First external terminal 51 is connected to first line 121. Each of second main terminal 52a and second auxiliary terminal 52b of second external terminal 52 is connected to second line 122.

This configuration makes it possible to inhibit the imbalance of differential line 120 in differential communication device 100. With this, differential communication device 100 that can inhibit the degradation of communication quality can be provided.

Differential communication device 100 according to present embodiment includes substrate 105C on which differential line 120 including first line 121 and second line 122 is provided, transceiver IC 160 mounted on substrate 105C, common mode filter 150 mounted on substrate 105C and connected to transceiver IC 160, and varistor component 1C mounted on substrate 105C and connected to common mode filter 150. First main terminal 51a of first external terminal 51 is connected to first line 121, first auxiliary terminal 51b of first external terminal 51 is not connected to first line 121, and each of second main terminal 52a and second auxiliary terminal 52b of second external terminal 52 is connected to second line 122.

This configuration makes it possible to inhibit the imbalance of differential line 120 in differential communication device 100. With this, differential communication device 100 that can inhibit the degradation of communication quality can be provided.

Differential communication device 100 according to present embodiment includes substrate 105C on which differential line 120 including first line 121 and second line 122 is provided, transceiver IC 160 mounted on substrate 105C, common mode filter 150 mounted on substrate 105C and connected to transceiver IC 160, and varistor component 1C mounted on substrate 105C and connected to common mode filter 150. Second main terminal 52a of second external terminal 52 is connected to second line 122, second auxiliary terminal 52b of second external terminal 52 is not connected to second line 122, and each of first main terminal 51a and first auxiliary terminal 51b of first external terminal 51 is connected to first line 121.

This configuration makes it possible to inhibit the imbalance of differential line 120 in differential communication device 100. With this, differential communication device 100 that can inhibit the degradation of communication quality can be provided.

### OTHER EMBODIMENTS

Hereinbefore, the varistor component and the like according to embodiments of the present disclosure and variations of the embodiments have been described, but the present disclosure is not limited to the above embodiments and variations. Various modifications to the exemplary embodiments and variations thereof that may be conceived by those skilled in the art, as well as other embodiments resulting from combinations of some elements of the exemplary embodiments and variations thereof, are intended to be included within the scope of the present disclosure as long as these do not depart from the essence of the present disclosure.

### INDUSTRIAL APPLICABILITY

The differential communication device according to the present disclosure is applicable as a communication device used in various electronic devices and communication systems. The varistor component according to the present disclosure is applicable as an electronic component used in differential communication devices.

1. A varistor component comprising:
a first varistor element; and
a second varistor element, wherein
an electrostatic capacitance of the first varistor element and an electrostatic capacitance of the second varistor element are different.

2. The varistor component according to claim 1, further comprising:
a varistor-material sintered body; and
a first internal electrode, a second internal electrode, and a third internal electrode provided inside the varistor-material sintered body, wherein,
at least a portion of the first internal electrode opposes the third internal electrode,
at least a portion of the second internal electrode opposes the third internal electrode,
a value of the electrostatic capacitance of the first varistor element varies depending on an opposing surface area between the first internal electrode and the third internal electrode,
a value of the electrostatic capacitance of the second varistor element varies depending on an opposing surface area between the second internal electrode and the third internal electrode, and
the opposing surface area between the first internal electrode and the third internal electrode is different from the opposing surface area between the second internal electrode and the third internal electrode.

3. The varistor component according to claim 2, wherein
the electrostatic capacitance of the second varistor element is greater than the electrostatic capacitance of the first varistor element, and
the opposing surface area between the second internal electrode and the third internal electrode is larger than the opposing surface area between the first internal electrode and the third internal electrode.

4. The varistor component according to claim 3, wherein
the varistor-material sintered body includes a bottom surface and a top surface facing in opposite directions, and a plurality of side surfaces perpendicular to the bottom surface and the top surface,
the plurality of side surfaces include a first side surface and a second side surface facing in opposite directions, and a third side surface and a fourth side surface facing in opposite directions and perpendicular to the first side surface and the bottom surface,
each of the first internal electrode, the second internal electrode, and the third internal electrode is provided parallel to the bottom surface or the top surface, and
when a direction parallel to the opposite directions in which the first side surface and the second side surface face is defined as a first direction, and a direction parallel to the opposite directions in which the third side surface and the fourth side surface face is defined as a second direction, a width dimension of the second internal electrode in the second direction is greater than a width dimension of the first internal electrode in the second direction.

5. The varistor component according to claim 4, further comprising:
a first external terminal provided on the first side surface, a second external terminal provided on the second side surface, and a third external terminal provided on at least one of the third side surface or the fourth side surface, wherein
the first internal electrode is connected to the first external terminal at the first side surface,
the second internal electrode is connected to the second external terminal at the second side surface, and
the third internal electrode is connected to the third external terminal at at least one of the third side surface or the fourth side surface.

6. The varistor component according to claim 5, wherein
the first external terminal is further provided on a portion of each of the bottom surface, the top surface, the third side surface, and the fourth side surface so as to connect to the first external terminal on the first side surface,
the second external terminal is further provided on a portion of each of the bottom surface, the top surface, the third side surface, and the fourth side surface, in regions other than regions where the first external terminal is provided, so as to connect to the second external terminal on the second side surface, and
on each of the top surface, the bottom surface, the third side surface, and the fourth side surface, a length of the second external terminal in the first direction is longer than a length of the first external terminal in the first direction.

7. The varistor component according to claim 5, further comprising:
an identification mark for distinguishing between the first external terminal and the second external terminal, wherein
the identification mark is provided on at least one of the bottom surface or the top surface.

8. The varistor component according to claim 5, wherein
the second internal electrode includes a second main electrode and a second auxiliary electrode that are not connected to each other,
the second external terminal includes a second main terminal and a second auxiliary terminal that are not connected to each other,
the second main electrode is connected to the second main terminal,
the second auxiliary electrode is connected to the second auxiliary terminal, and
an electrostatic capacitance formed by the second main electrode and the third internal electrode is same as an electrostatic capacitance formed by the first internal electrode and the third internal electrode.

9. The varistor component according to claim 8, wherein
an opposing surface area between the second main electrode and the third internal electrode is same as the opposing surface area between the first internal electrode and the third internal electrode, and
an opposing surface area between the second auxiliary electrode and the third internal electrode is smaller than the opposing surface area between the second main electrode and the third internal electrode.

10. The varistor component according to claim 3, wherein
the electrostatic capacitance of the second varistor element is less than or equal to 1.12 times the electrostatic capacitance of the first varistor element.

11. A varistor component comprising:
a first varistor element;
a second varistor element;
a varistor-material sintered body;
a first internal electrode, a second internal electrode, and a third internal electrode provided inside the varistor-material sintered body; and
a first external terminal connected to the first internal electrode, a second external terminal connected to the second internal electrode, and a third external terminal connected to the third internal electrode, wherein
the first internal electrode includes a first main electrode and a first auxiliary electrode that are not connected to each other,
the second internal electrode includes a second main electrode and a second auxiliary electrode that are not connected to each other,
the first external terminal includes a first main terminal and a first auxiliary terminal that are not connected to each other,
the second external terminal includes a second main terminal and a second auxiliary terminal that are not connected to each other,
the first main electrode is connected to the first main terminal,
the first auxiliary electrode is connected to the first auxiliary terminal,
the second main electrode is connected to the second main terminal,
the second auxiliary electrode is connected to the second auxiliary terminal,
at least a portion of the first main electrode and at least a portion of the first auxiliary electrode oppose the third internal electrode,
at least a portion of the second main electrode and at least a portion of the second auxiliary electrode oppose the third internal electrode,
an electrostatic capacitance formed by the first main electrode and the third internal electrode is same as an electrostatic capacitance formed by the second main electrode and the third internal electrode, and
an electrostatic capacitance formed by the first auxiliary electrode and the third internal electrode is same as an electrostatic capacitance formed by the second auxiliary electrode and the third internal electrode.

12. The varistor component according to claim 11, wherein
the varistor-material sintered body includes a bottom surface and a top surface facing in opposite directions, and a plurality of side surfaces perpendicular to the bottom surface and the top surface,
in a view of the varistor component along a central axis passing through a center of the bottom surface and a center of the top surface:
the first main electrode and the second main electrode are point-symmetrical with respect to the central axis; and
the first auxiliary electrode and the second auxiliary electrode are point-symmetrical with respect to the central axis.

13. A differential communication device comprising:
a transceiver IC;
a common mode filter connected to the transceiver IC; and
the varistor component according to claim 1 connected to the common mode filter.

14. A differential communication device comprising:
a substrate on which a differential line including a first line and a second line is provided;
a transceiver IC mounted on the substrate;
a common mode filter mounted on the substrate and connected to the transceiver IC; and
the varistor component according to claim 1 mounted on the substrate and connected to the common mode filter.

15. A differential communication device comprising:
a substrate on which a differential line including a first line and a second line is provided;
a transceiver IC mounted on the substrate;
a common mode filter mounted on the substrate and connected to the transceiver IC; and
the varistor component according to claim 8 mounted on the substrate and connected to the common mode filter, wherein
the first external terminal is connected to the first line, and
each of the second main terminal and the second auxiliary terminal of the second external terminal is connected to the second line.

16. A differential communication device comprising:
a substrate on which a differential line including a first line and a second line is provided;
a transceiver IC mounted on the substrate;
a common mode filter mounted on the substrate and connected to the transceiver IC; and
the varistor component according to claim 11 mounted on the substrate and connected to the common mode filter, wherein
the first main terminal of the first external terminal is connected to the first line,
the first auxiliary terminal of the first external terminal is not connected to the first line, and
each of the second main terminal and the second auxiliary terminal of the second external terminal is connected to the second line.

17. A differential communication device comprising:
a substrate on which a differential line including a first line and a second line is provided;
a transceiver IC mounted on the substrate;
a common mode filter mounted on the substrate and connected to the transceiver IC; and
the varistor component according to claim 11 mounted on the substrate and connected to the common mode filter, wherein
the second main terminal of the second external terminal is connected to the second line,
the second auxiliary terminal of the second external terminal is not connected to the second line, and
each of the first main terminal and the first auxiliary terminal of the first external terminal is connected to the first line.
